(19) United States
(12) Patent Application Publication
(10) Pub. No.: US 2025/0287658 A1
(43) Pub. Date: Sep. 11, 2025

(54) SEMICONDUCTOR DEVICE AND METHOD OF FORMING THE SAME

(71) Applicant: TAIWAN SEMICONDUCTOR MANUFACTURING COMPANY, LTD., Hsinchu (TW)

(72) Inventor: Chih-Yang CHEN, Hsinchu City (TW)

(73) Assignee: TAIWAN SEMICONDUCTOR MANUFACTURING COMPANY, LTD., Hsinchu (TW)

(21) Appl. No.: 18/601,535

(22) Filed: Mar. 11, 2024

(51) Int. Cl. H01L 29/06; H01L 21/762; H01L 29/423; H01L 29/66; H01L 29/775; H01L 29/786

(52) U.S. Cl. CPC H10D 62/121; H01L 21/76232; H10D 30/014; H10D 30/43; H10D 30/6735; H10D 30/6757; H10D 64/018

(57) ABSTRACT

A method includes a number of operations. A semiconductor stack structure is formed over a substrate, wherein the semiconductor stack structure includes a first semiconductor stack including first channel layers, a second semiconductor stack including second channel layers over the first semiconductor stack and a sacrificial layer between the first and second semiconductor stack. The semiconductor stack structure is etched through, wherein the sacrificial layer is etched such that a top width of the sacrificial layer is different from a bottom width of the sacrificial layer. The etched sacrificial layer is removed. An isolation layer is formed between the first and second semiconductor stacks. First and second source/drain regions are formed on opposite sides of first and second channel layers. First and second gate structures are formed and around the first and second channel layers.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 17B illustrate a method in various stages of forming a semiconductor device in accordance with some embodiments of the present disclosure.

FIGS. 18 to 24 illustrate a method in various stages of forming a semiconductor device in accordance with some embodiments of the present disclosure.

FIGS. 25 and 26 illustrate a method in various stages of forming a semiconductor device in accordance with some embodiments of the present disclosure.

FIGS. 27 to 33 illustrate cross-section views of channel regions and metal gate structures of various semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is generally related to a semiconductor device of a Complementary Field-Effect Transistor (CFET) structure. While Gate-All-Around (GAA) transistors (such as nanostructure-FETs) are discussed, the concept of the present disclosure can also be applied to the formation of other types of transistors such as planar transistors, Fin Field-Effect Transistors (FinFETs), or the like. Furthermore, in the illustrated examples, the upper FETs are PFETs, and lower FETs are NFETs, while in other embodiments, upper FETs may also be NFETs, and the lower FETs may be PFETs.

The CFET structure offers a promising opportunity to significantly reduce the integrated circuit footprint. The CFET structure may include a bottom transistor and a top transistor overlapping and electrically connected to the bottom transistor. The top and bottom transistors of the CFET structure may be formed by commonly patterning a semiconductor stack of nanostructures, and the top and bottom transistor of the CFET structure may have gate structures with similar dimensions and profiles due to commonly patterning process to the semiconductor stack of nanostructures. In one or more embodiments of the present disclosure, for device tuning feasibility, multi-steps etching process may be performed to one or more layers of the nanostructures used for forming the top and bottom transistors of the CFET structure, so that the profiles of the top and bottom transistors and isolation structures between the top and bottom transistors in the formed CFET structure may be controlled. For example, the isolation structure between the top and bottom transistors in the formed CFET structure may have opposite bottom and top surfaces having different widths, so that the metal gate structures of the top and bottom transistors may have different dimensions.

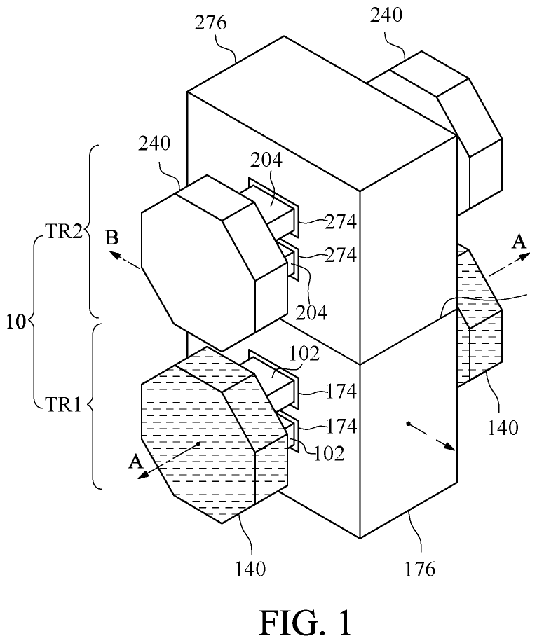

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 204 vertically stacked one above another, a second metal gate structure 270 wrapping around each of the second semiconductor channel layers 204, and second source/drain epitaxy structures 240 on opposite ends of each of the second semiconductor channel layers 204. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, the first transistor TR1 has a first conductivity type (e.g., n-type) and the second transistor TR2 has a second conductivity type (e.g., p-type) different from the first conductivity type. In some embodiments, the first transistor TR1 can be referred to as an N-FET, and the second transistor TR2 can be referred to as a P-FET. In some embodiments, the first semiconductor channel layers 102 may include material suitable for N-type device, such as silicon (Si), while the second semiconductor channel layers 204 may include material suitable for P-type device, such as silicon germanium (SiGe).

In some embodiments, the bottom transistor TR1 and the top transistor TR2 and can have single or multiple nanosheet channels. The number of nanosheet channel of the bottom transistor TR1 and the top transistor TR2 can be the same or different.

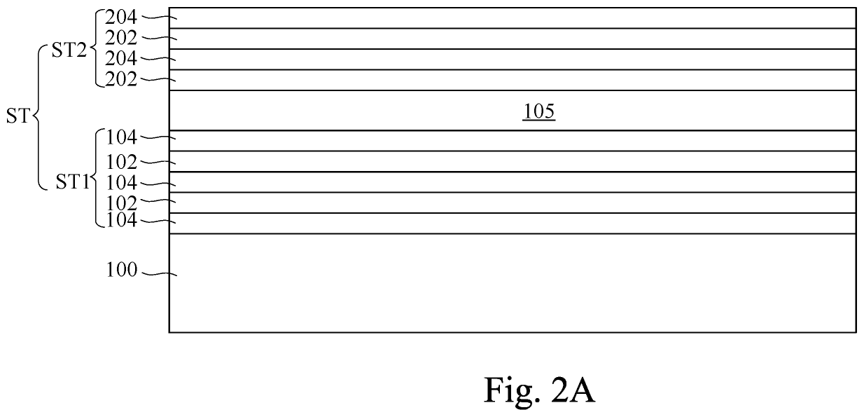

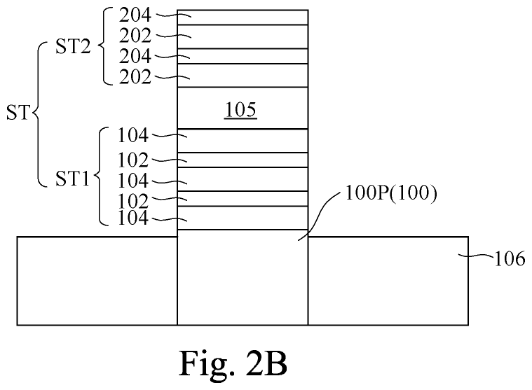

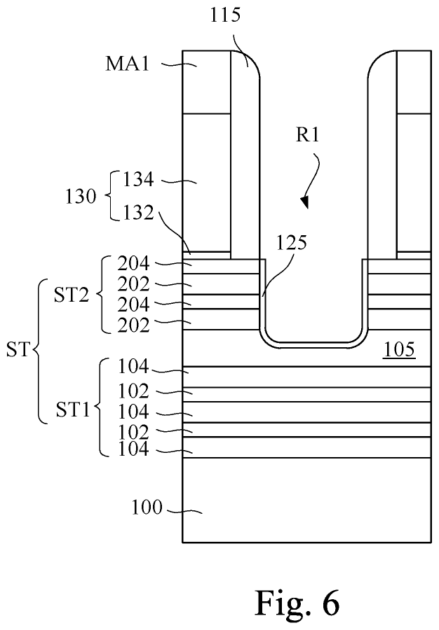

FIGS. 2A to 17B illustrate a method in various stages of forming a semiconductor device in accordance with some embodiments of the present disclosure. In greater detail, FIGS. 2A to 17B illustrate a method for forming a detailed structure of the CFET 10 of FIG. 1. It is noted that FIGS. 2A, 3A, 4A, 5A, 10A, 11A, 12A, 13A, 14A, 15A, 16A, 17A include cross-sectional views the same as the cross-sectional view along line A-A of FIG. 1, FIGS. 6-9 includes cross-sectional views multi-steps etching process to the semiconductor stacks, and FIGS. 2B, 3B, 4B, 5B, 10B, 11B, 12B, 13B, 14B, 15B, 16B, 17B include cross-sectional views the same as the cross-sectional view along line B-B of FIG. 1.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the semiconductor layers 104 and 204 is in a range from about 20 percent and about 50 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es).

A patterning process may be performed to the semiconductor stack ST and the substrate 100 to form a fin structure, as shown in FIG. 2B. In some embodiments, the patterning process may include forming a patterned photoresist layer over the stack ST, and then performing an etching process to remove unwanted portions of the semiconductor stack ST and the substrate 100 exposed by the patterned photoresist layer. The fin structure may include a remaining portion of the semiconductor stack ST and a semiconductor strip 100P protruding over the substrate 100. In some embodiments, the etching process may include wet etch, dry etch, or the like.

After the fin structure is formed, isolation structures 106 are formed over the substrate 100 and laterally surrounding the fin structure. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

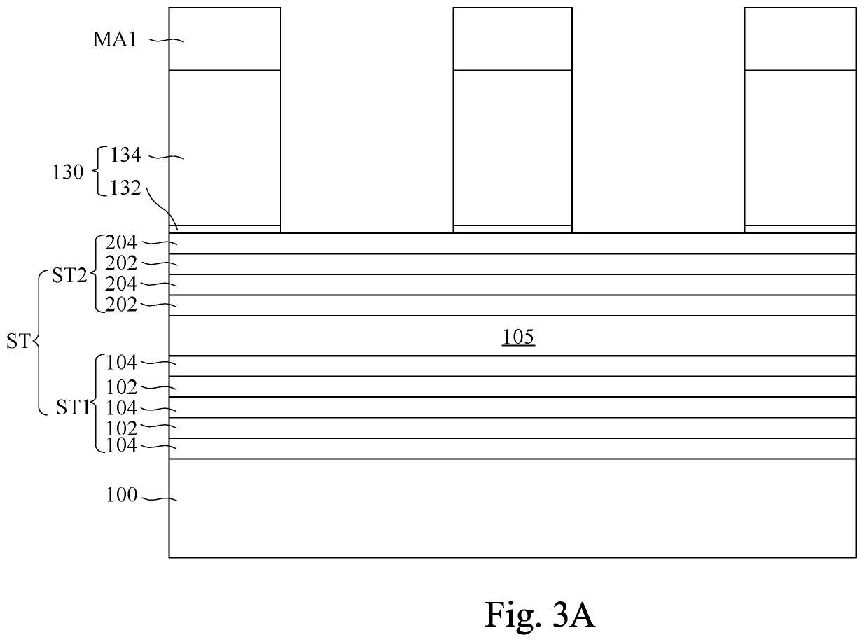

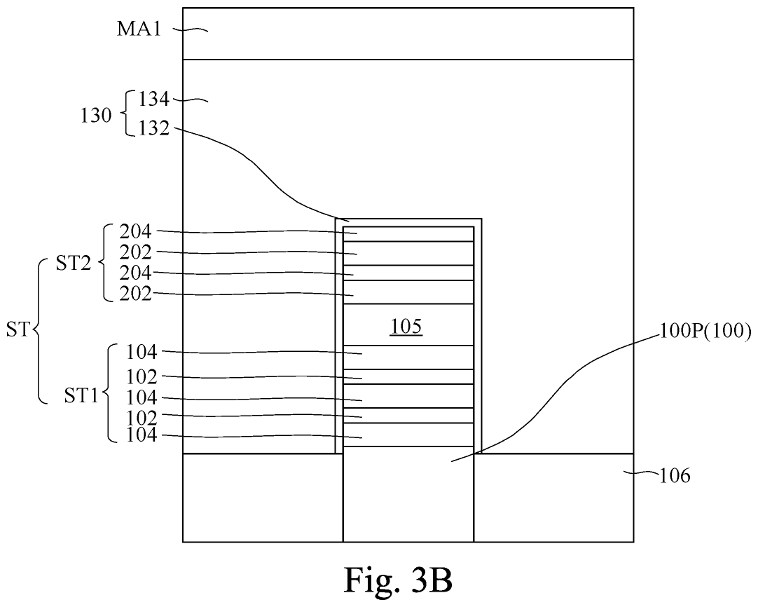

Reference is made to FIGS. 3A and 3B. Dummy gate structures 130 are formed over the substrate 100 and crossing the fin structure. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes one or more hard masks. The one or more hard masks may be made of different materials. In some embodiments, the one or more hard masks of the patterned masks MA1 may include a silicon nitride layer and a silicon oxide layer.

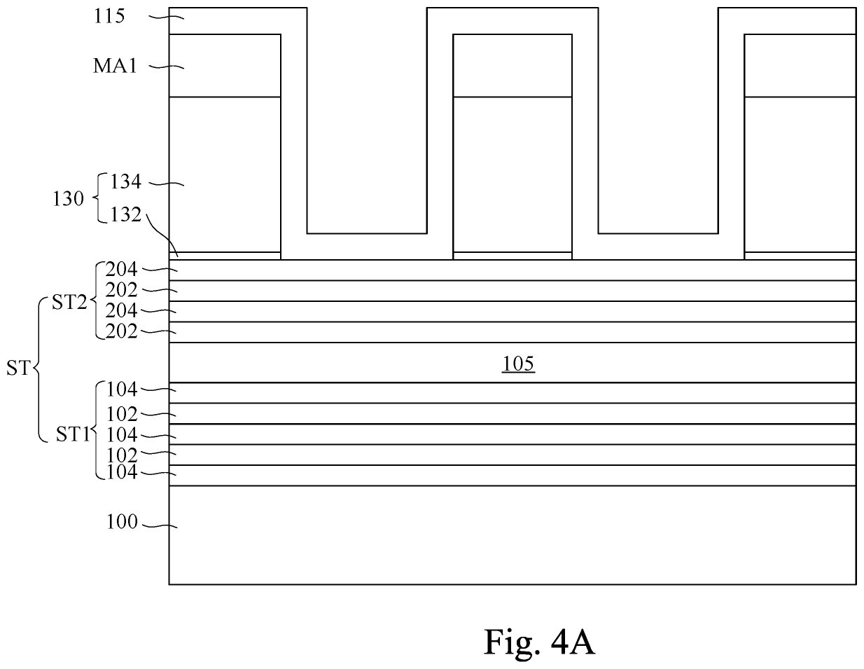

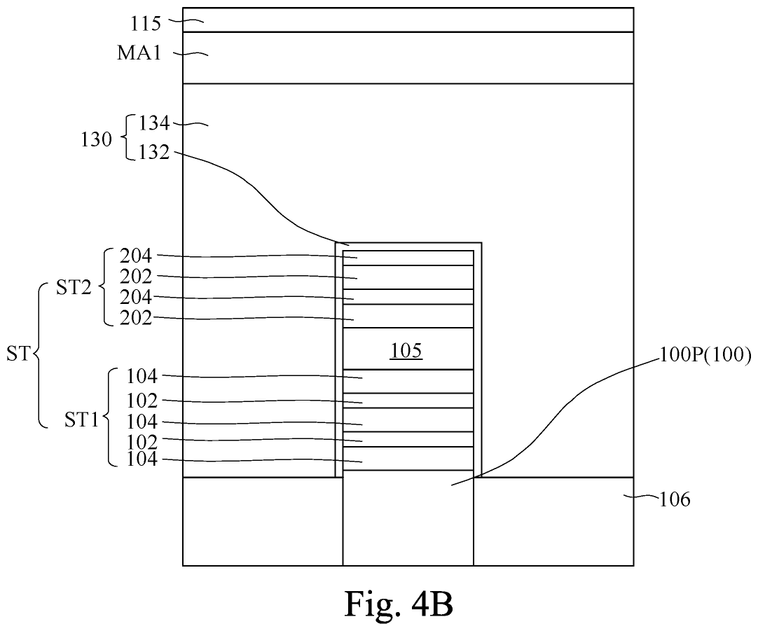

Reference is made to FIGS. 4A and 4B. A spacer layer 115 is deposited conformally over the structure of FIGS. 3A and 3B. In some embodiments, the spacer layer 115 may be formed of silicon oxide, silicon nitride, silicon oxynitride, combinations thereof, using techniques such as thermal oxidation or deposited by CVD, ALD, or the like.

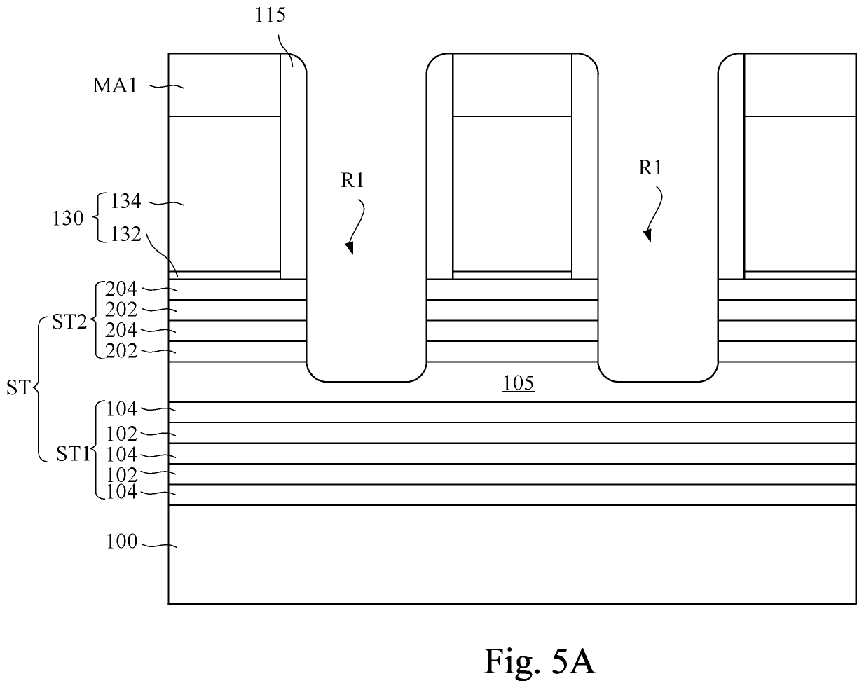

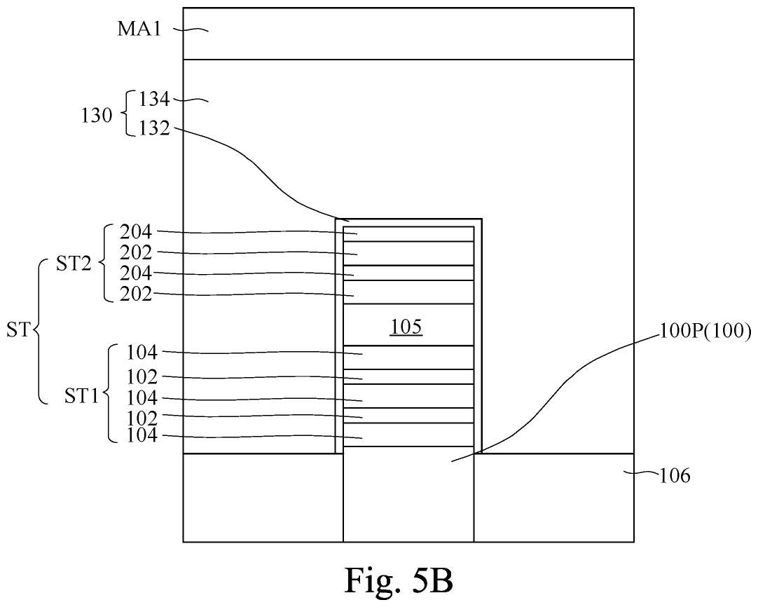

Reference is made to FIGS. 5A and 5B. In some embodiments, an anisotropic etching process is performed to remove horizontal portions of the spacer layer 115, such that vertical portions of the spacer layer 115 remain on sidewalls of the dummy gate structures 130. In some embodiments, the remaining vertical portions of the spacer layer 115 on sidewalls of the dummy gate structures 130 can be referred to as gate spacers 115.

After the gate spacers 115 are formed, an etching process is performed, by using the gate spacers 115 and the patterned masks MA1 (or the dummy gate structures 130) as etch mask, to remove portions of the second stack ST2. As illustrated in FIG. 5A, the second stack ST2 is etched through. In greater detail, the etching process removes portions of the semiconductor layers 202 and 204, so as to form recesses R1 in the second stack ST2. In some embodiments, the semiconductor layer 105 may include higher etch resistance to the etching process than the semiconductor layers 202 and 204, and thus the semiconductor layer 105 may act as an etch stop layer during the etching process. As a result, the etching process may be stopped at the semiconductor layer 105, and thus the underlying semiconductor layers 102 and 104 are protected by the semiconductor layer 105 and may keep substantially intact after the etching process is complete. In some embodiments, the exposed portions of the semiconductor layer 105 may be slightly etched during the etching process, and thus the bottom surfaces of the recesses R1 may be lower than top surface of the semiconductor layer 105. In some embodiments, the etching process may be wet etch, dry etch, or combinations thereof.

In one or more embodiments of the present disclosure, after the recess R1 is formed and extends through the second stack ST2 and into the semiconductor layer 105, the semiconductor layer 105 is etched to have a designed profile. For example, the etched semiconductor layer 105 may have an opening having different top and bottom widths. The first stack ST1 may be etched through based on the bottom width of the through opening in the etched semiconductor layer 105, so that the etched second stack ST2 may have different dimension from the first stack ST1. FIGS. 6 through 9 are local cross-sectional views near the recess R1 and schematically illustrate etching of the semiconductor layer 105 in various stages in accordance with some embodiments of the present disclosure.

Reference is made to FIG. 6. A mask layer 125 is formed lining sidewall surfaces of the semiconductor layers 202 and the semiconductor channel layers 204 and is formed over a bottom of the recess R1 in the semiconductor layer 105. As shown in FIG. 6, the mask layer 125 is free from the gate spacer 115.

In some embodiments, the mask layer 125 may be formed by, for example, depositing a polymer layer over the sidewall surfaces of the semiconductor layers 202 and the semiconductor channel layers 204 and exposed surface of the semiconductor layer 105. In some embodiments, the mask layer 125 of the polymer layer may include carbon, hydrogen and oxygen. In some embodiments, the mask layer 125 of the polymer layer is formed by providing chlorine or fluorine radical to the exposed surfaces of the semiconductor layers 202, the semiconductor channel layers 204 and the semiconductor layer 105, and the mask layer 125 of the polymer layer may include chlorine or fluorine.

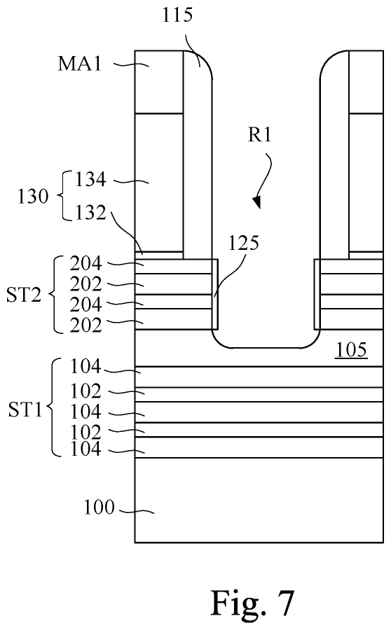

Reference is made to FIG. 7. The mask layer 125 is patterned. In some embodiments, the mask layer 125 is patterned by an anisotropic etching process, so that horizontal portions of the mask layer 125 is removed to expose the semiconductor layer 105. The remaining vertical portions can be referred to as the etch mask 125.

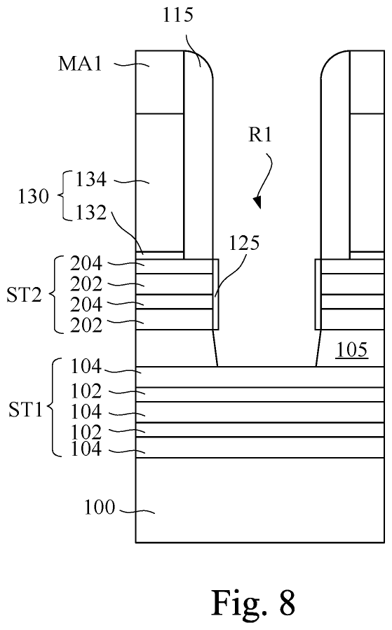

Reference is made to FIG. 8. The semiconductor layer 105 exposed from the mask layer 125 is etched based on the mask layer 125. In some embodiments, the semiconductor layer 105 may be etched by the etching process to the semiconductor layers 202 and the semiconductor channel layers 204 of the second stack ST2. It is noted that the sidewalls of the semiconductor layers 202 and the semiconductor channel layers 204 is covered by the mask layer 125 and protected by the mask layer 125 from being etched. As shown in FIG. 8, the semiconductor layer 105 is etched through.

A width of the bottom end of the through opening formed in the semiconductor layer 105 may be controlled by a thickness of the mask layer 125 since the semiconductor layer 105 is etched through based on the space occupied by the mask layer 125. The more space occupied by the mask layer 125, i.e., the thicker thickness the mask layer 125 has, the less bottom width of the through opening formed in the semiconductor layer 105.

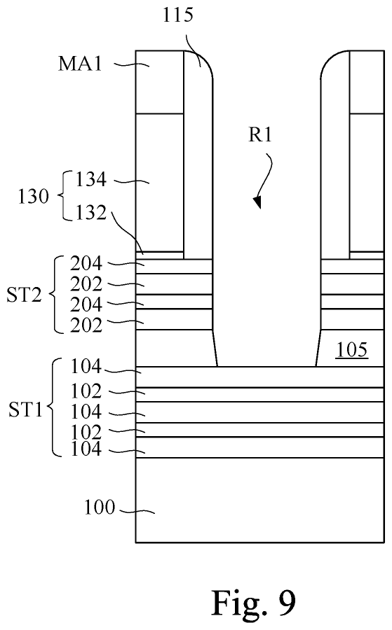

Reference is made to FIG. 9. After the semiconductor layer 105 is etched through, in FIG. 9, the remaining mask layer 125 is removed. An opening is formed through the semiconductor layer 105. Since the semiconductor layer 105 is etched based on the mask layer 125 occupying space in the recess R1, and the opening through the semiconductor layer 105 narrows from top to bottom. The semiconductor layer 105 may have a top width and a bottom width greater than the top width.

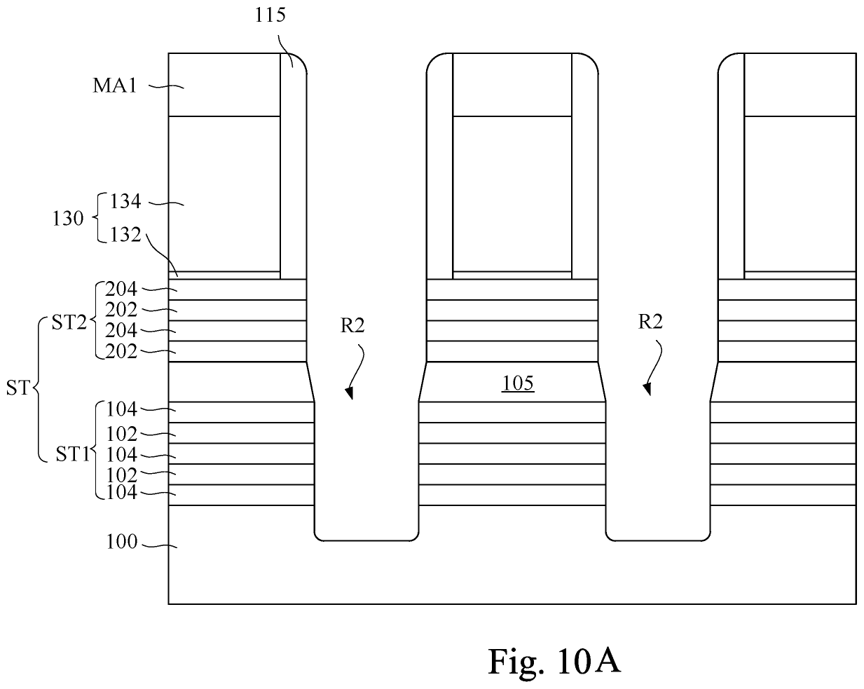

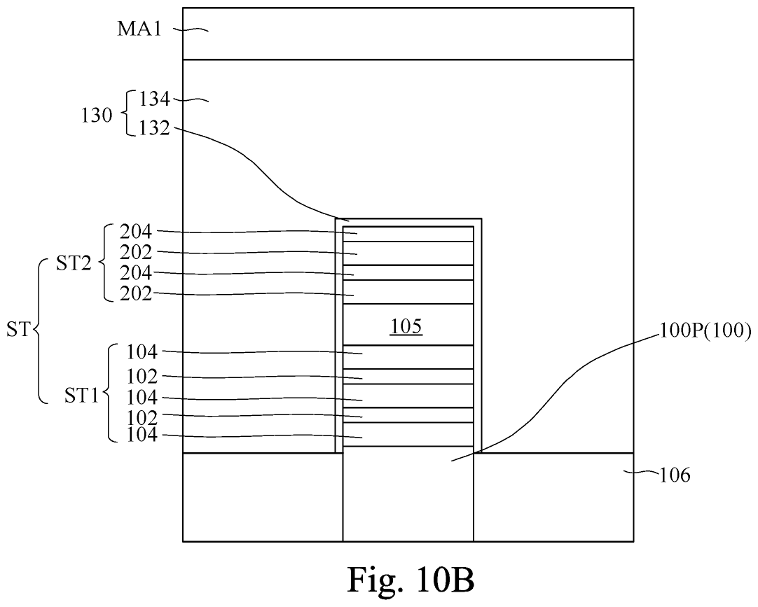

Reference is made to FIGS. 10A and 10B. An etching process is performed to the semiconductor channel layers 102 and the semiconductor layers 104 of the first semiconductor stack ST1 based on the patterned semiconductor layer 105. In greater detail, the etching process removes portions of the semiconductor layers 102 and 104, so as to form recesses R2 in the first stack ST1. In some embodiments, the exposed portions of the substrate 100 may be slightly etched during the etching process, and thus the bottom surfaces of the recesses R2 may be lower than top surface of the substrate 100. In some embodiments, the etching process may be wet etch, dry etch, or combinations thereof. In some embodiments, mask layers may be formed and used to protect the semiconductor layers 202 and the semiconductor channel layers 204 of the second stack ST2 during the etching process, and thus the semiconductor layers 204 may keep substantially intact after the etching process is complete. The mask layers used for protecting the semiconductor layers 202 and the semiconductor channel layers 204 of the second stack ST2 may be removed after the recess R2 is formed.

Since each of the etched semiconductor layer 105 has the top surface wider than the bottom width, a width of the semiconductor layers 202 and the semiconductor channel layers 204 above the etched semiconductor layer 105 is greater than a width the semiconductor channel layers 102 and the semiconductor layers 104 under the semiconductor layer 105.

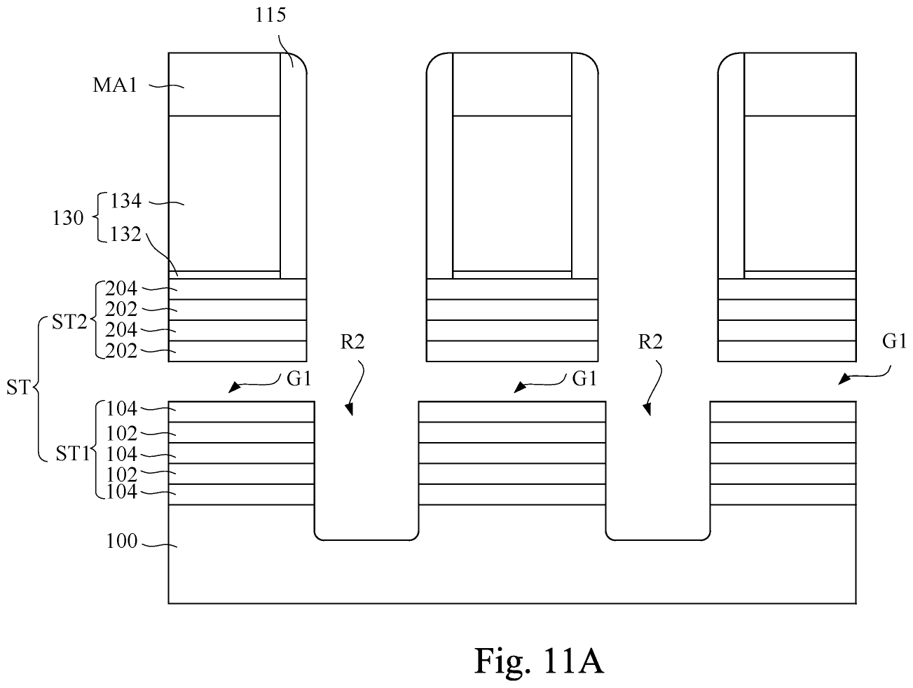

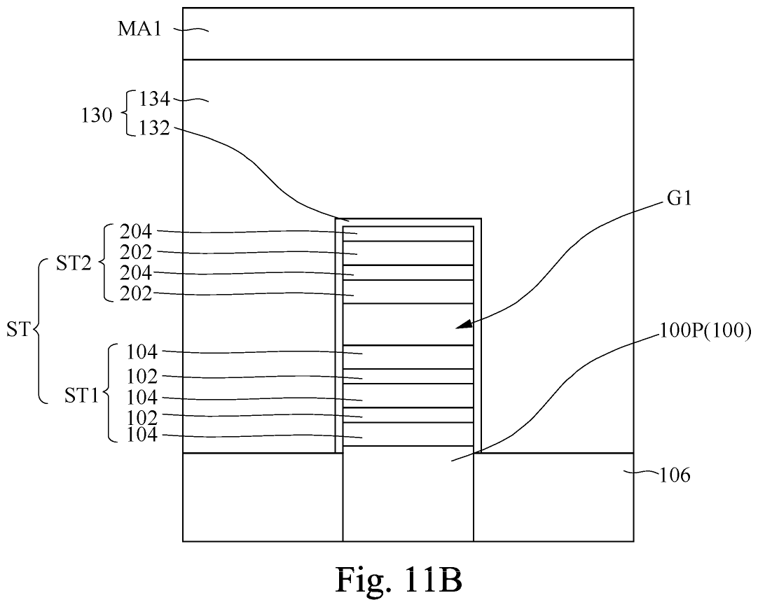

Reference is made to FIGS. 11A and 11B. An etching process is performed to remove the semiconductor layer 105 through the recesses R1 and R2. In greater detail, each of the gaps G1 is vertically between the topmost semiconductor layer 104 and the bottommost semiconductor layer 202. In some embodiments, the semiconductor layers 102, 104, 202, and 204 may include higher etch resistance to the etching process than the semiconductor layer 105, and thus the semiconductor layers 102, 104, 202, and 204 may keep substantially intact after the etching process is complete. In some embodiments, the etching process may be wet etch, dry etch, or combinations thereof. In some embodiments, the semiconductor layer 105 may be regarded as a sacrificial layer.

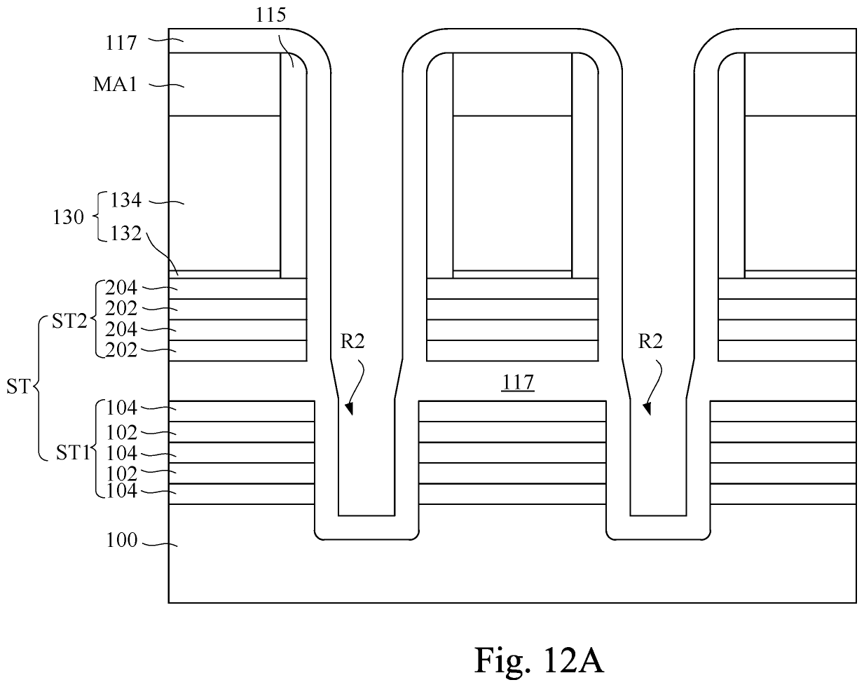

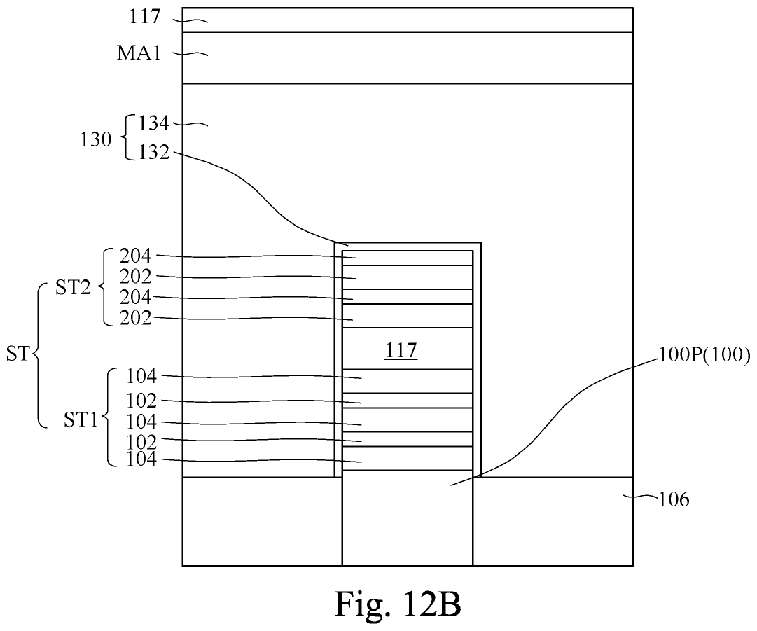

Reference is made to FIGS. 12A and 12B. An isolation layer 117 is deposited blanket over the substrate 100 and filling the gaps G1. The isolation layer 117 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

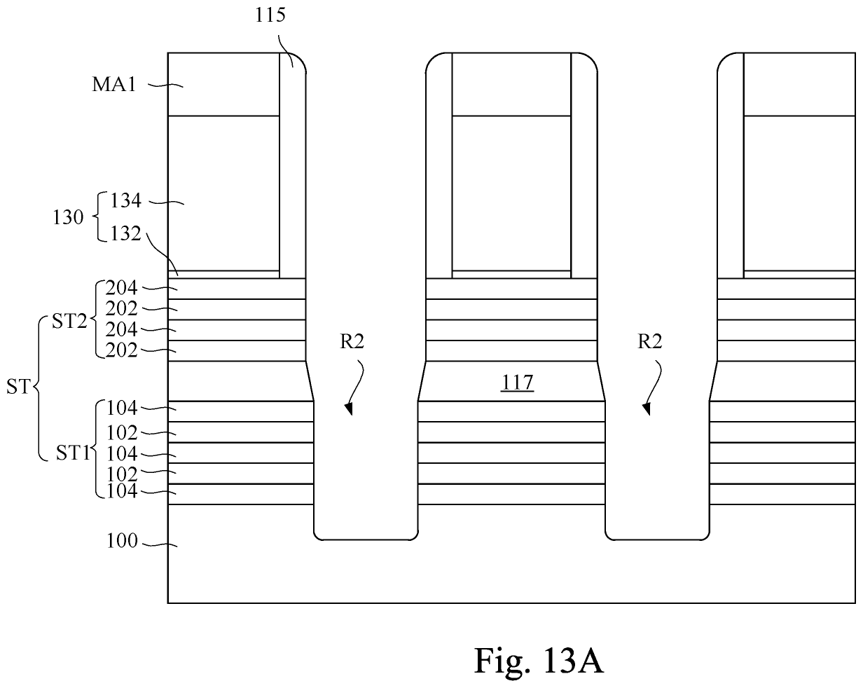

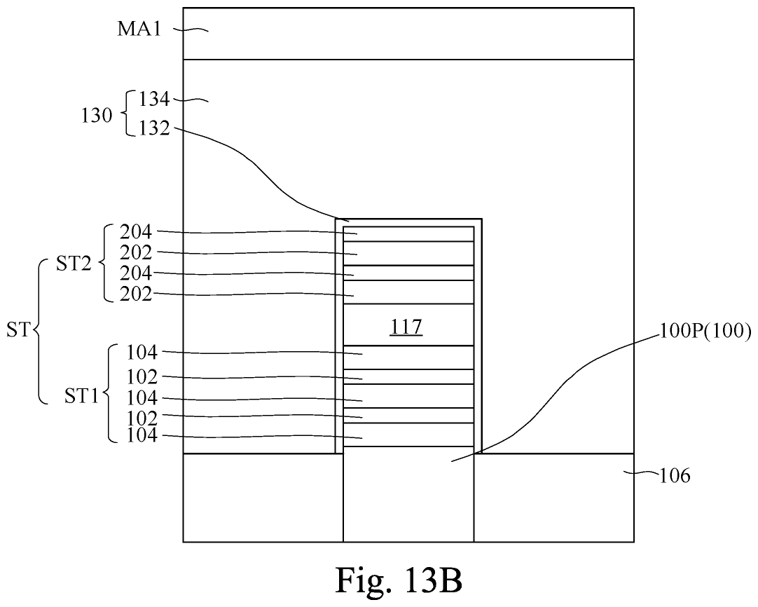

Reference is made to FIGS. 13A and 13B to illustrate etching back the isolation layer 117. In some embodiments, an anisotropic etching process is performed to remove portions of the isolation layer 117 outside the gaps G1, and the remaining portions of the isolation layer 117 are present between the topmost semiconductor layer 104 and the bottommost semiconductor layer 202. As a result, the portion of the semiconductor layer 105 between the topmost semiconductor layer 104 and the bottommost semiconductor layer 202 is replaced with the isolation layer 117. As shown in FIG. 13A, the isolation layer 117 has a top surface and a bottom surface wider than the top surface.

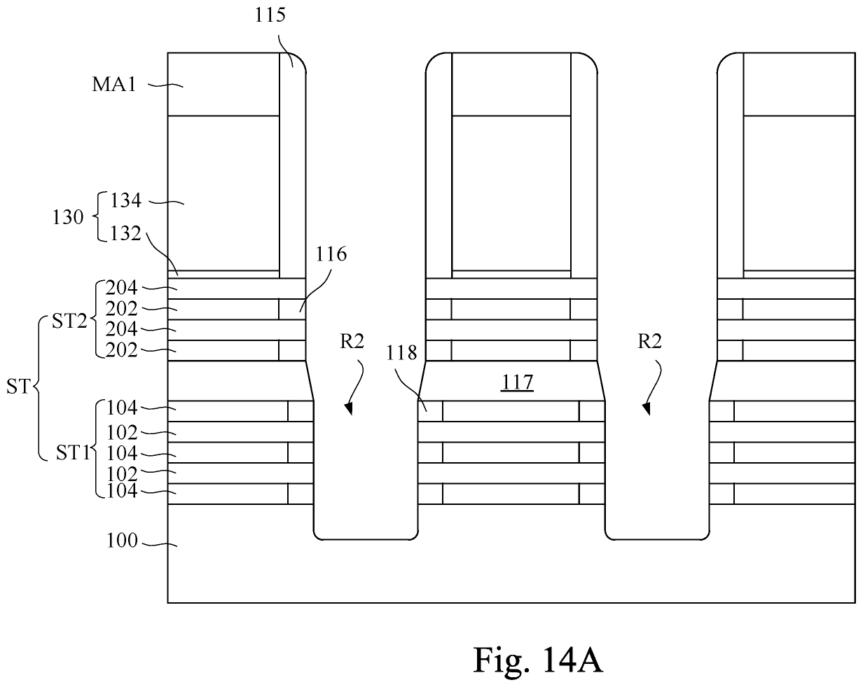

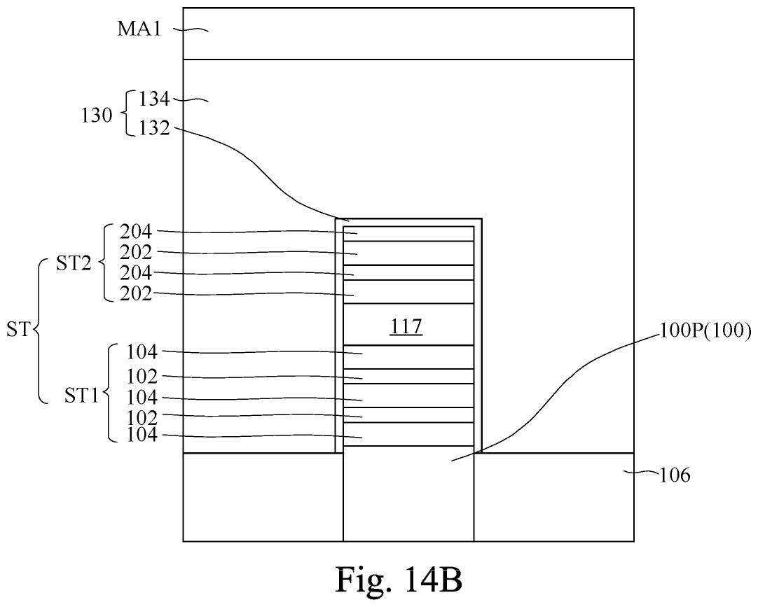

Reference is made to FIGS. 14A and 14B. The semiconductor layers 104 and 202 are laterally etched to form sidewall recesses. Then, inner spacers 116 are formed in the sidewall recesses on opposite ends of each of the semiconductor layers 202, and inner spacers 118 are formed in the sidewall recesses on opposite ends of each of the semiconductor layers 104. In some embodiments, the inner spacers 116 and 118 may be formed by, for example, depositing an inner spacer layer blanket over the substrate 100 and filling the sidewall recesses on opposite sides of the semiconductor layers 202 and 104, and then performing an anisotropic etching to remove portions of the inner spacer layer outside the sidewall recesses, leaving the remaining portions of the inner spacer layer in the sidewall recesses as the inner spacers 116 and 118. The inner spacers 116 and 118 may be deposited by a conformal deposition process, such as CVD, ALD, or the like. The inner spacer layer may include a material such as SiN, SiOCN, SiCN, SIOC, although any suitable material, such as low-dielectric constant (low-k) materials having a k-value less than about 3.5, may be utilized.

As shown in FIG. 14A, the inner spacers 118 on opposite sidewalls of the semiconductor layers 202 are laterally offset from the inner spacers 116 on opposite sidewalls of the semiconductor layers 104.

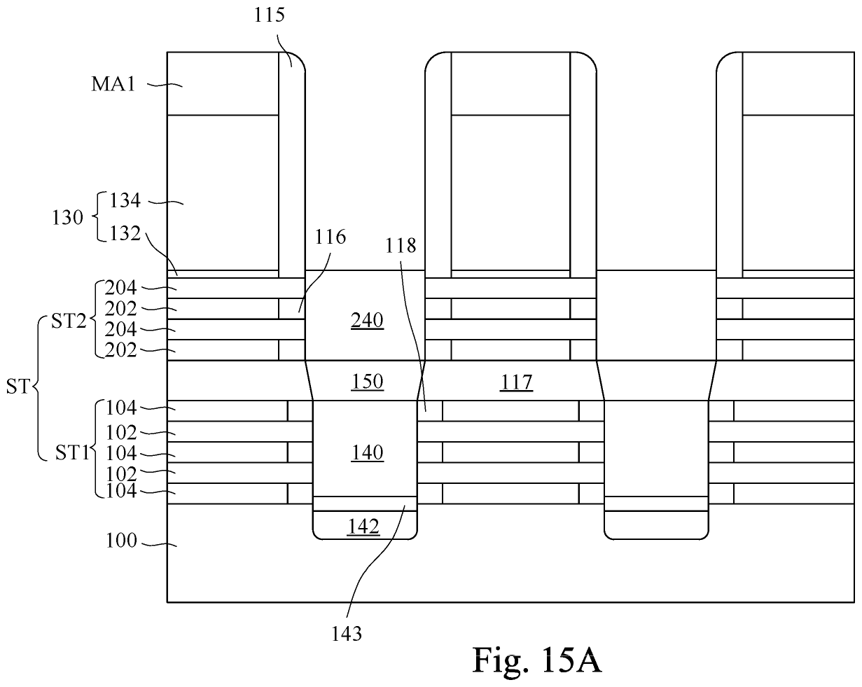

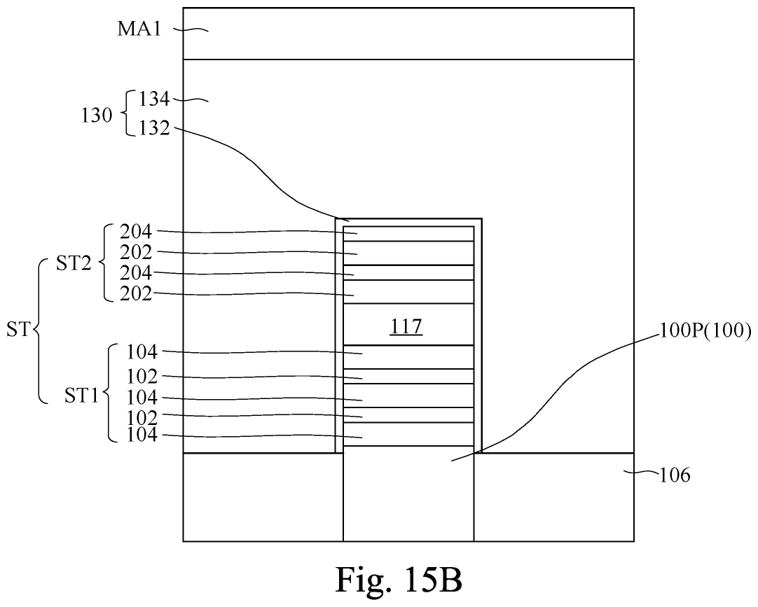

Reference is made to FIGS. 15A and 15B. Epitaxy layers 142 are formed at bottoms of the recesses R2, dielectric layers 143 are formed over the epitaxy layers 142, and then first source/drain epitaxy structures 140 are formed over the dielectric layers 143 and in contact with opposite ends of the semiconductor layers 102. In some embodiments, the formation of the epitaxy layers 142 may include a plurality of deposition cycles, in which each deposition cycle may include a selective epitaxial growth (SEG) process and an etching process. The dielectric layers 143 may be formed by depositing a dielectric material in the recesses R2 and then etching back the dielectric material. The first source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the epitaxy layers 142 and the exposed surfaces of the semiconductor layers 102. In some embodiments, the first source/drain epitaxy structures 140 may include SiAs, SiP, or combination of SiAs and SiP. In some embodiments, an implantation process may be performed to the first source/drain epitaxy structures 140. For example, the implantation process may include n-type dopants, such as phosphorus (P), arsenic (As), or antimony (Sb), or the like, such that the first source/drain epitaxy structures 140 are n-type epitaxy structures. In some embodiments, the epitaxy layers 142 may be formed without performing an implantation process, and thus the epitaxy layers 142 are un-doped. In some embodiments, the dielectric layers 143 are made of silicon nitride (SiN). The dielectric layers 143 may reduce current leakage from the first source/drain epitaxy structures 140 to the substrate 100.

Then, isolation structures 150 are formed over the first source/drain epitaxy structures 140, respectively. The isolation structures 150 may be formed by, for example, depositing dielectric material(s) over the first source/drain epitaxy structures 140, and then etching back the dielectric material(s). In some embodiments, the isolation structures 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. As shown in FIG. 15A, the isolation structures 150 are formed along the taper sidewalls of the isolation layer 117, so that the isolation structure 150 has a width changing as a function of height. Therefore, the isolation structures 150 form sloped interfaces with the isolation layers 117.

Second source/drain epitaxy structures 240 are formed on opposite ends of each of the semiconductor layers 204. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 204. In some embodiments, the second source/drain epitaxy structures 240 may include SiB, SiGe, or combination of SiB and SiGe. In some embodiments, an implantation process may be performed to the second source/drain epitaxy structures 240. For example, the implantation process may include p-type dopants, such as boron (B), gallium (Ga), indium (In), aluminium (Al), or the like, such that the second source/drain epitaxy structures 240 are p-type epitaxy structures.

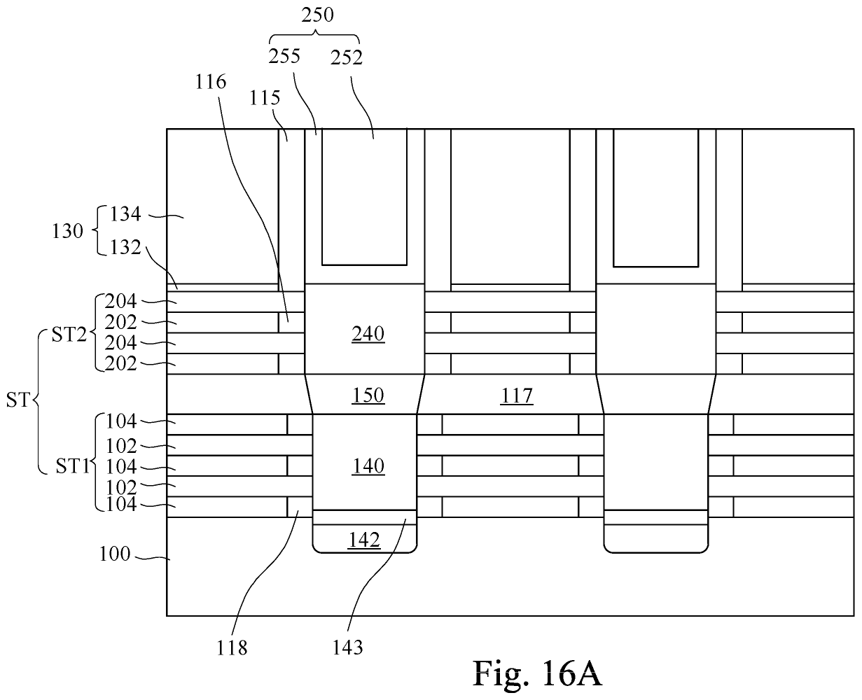

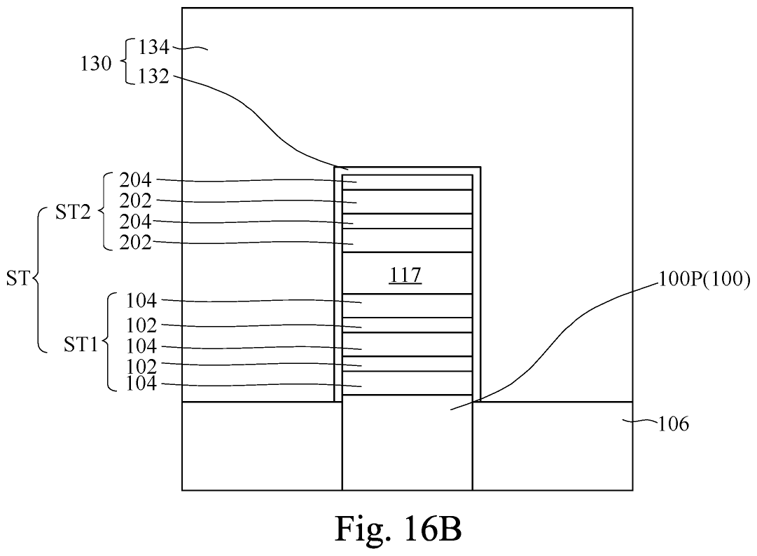

Reference is made to FIGS. 16A and 16B. Isolation structures 250 are formed over the second source/drain epitaxy structures 240, respectively. Each of the isolation structures 250 may include a contact etch stop layer (CESL) 255 and an interlayer dielectric (ILD) layer 252 over the CESL 255. The isolation structures 250 may be formed by, for example, depositing dielectric material(s) over the second source/drain epitaxy structures 240, and then performing a planarization process, such as CMP, to remove excess dielectric material(s). In some embodiments, during the planarization process, the patterned masks MA1 are removed, and the dummy gate structures 130 are exposed after the planarization process is complete.

In some embodiments, the CESL 255 may be a dielectric layer including silicon nitride, silicon oxynitride or other suitable materials. In some embodiments, the ILD layer 252 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 255 and the ILD layer 252 can be formed using, for example, CVD, ALD or other suitable techniques.

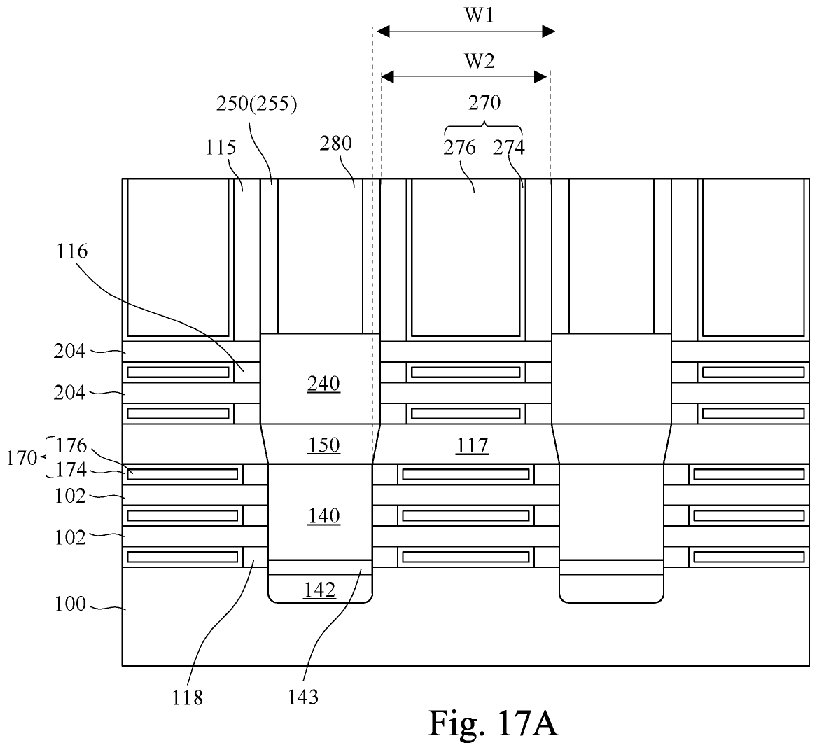

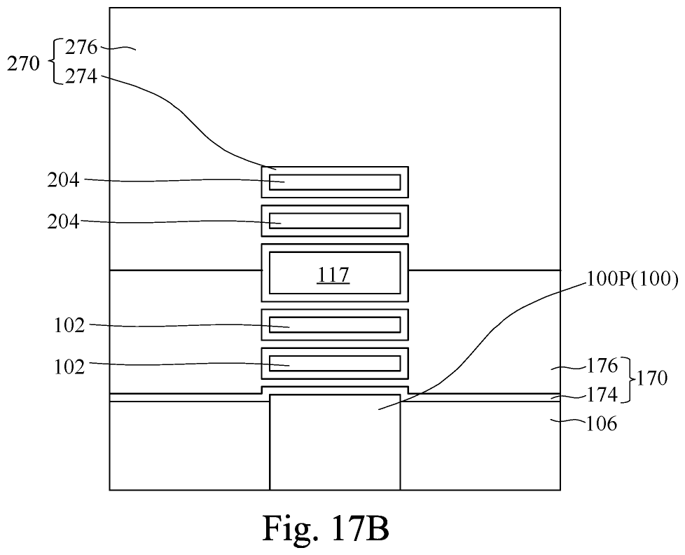

Reference is made to FIGS. 17A and 17B. The dummy gate structure 130 and the semiconductor layers 202 and 104 are removed, and the metal gate structures 170 and 270 are formed and warp around the semiconductor channel layers 102 and 204, respectively.

In some embodiments, the dummy gate structures 130 are removed to form gate trenches exposing the semiconductor layers 202 and 104. The semiconductor layers 202 and 104 are then removed through the gate trenches, such that the semiconductor channel layers 204 and 102 are suspended over the substrate 100. In some embodiments, the semiconductor layers 202 and 104 may be removed using suitable etching process. In some embodiments, the semiconductor layers 202 and 104 can also be referred to as sacrificial layers.

After the dummy gate structure 130, the semiconductor layers 202 and 104 are removed, gate dielectric layers 174 and 274 are formed wrapping around the semiconductor layers 102 and 204, respectively. In some embodiments, the gate dielectric layers 174 and 274 may be formed using a same deposition process. In some embodiments, interfacial layers (not shown) may be formed over the semiconductor layers 102 and 204 prior to forming the gate dielectric layers 174 and 274. In the cross-sectional view of FIG. 17B, a dielectric layer made of a same material as the gate dielectric layers 174 and 274 may wrap around the isolation layer 117.

Then, gate electrodes 176 are formed over the gate dielectric layers 174. Accordingly, first metal gate structures 170 are formed. In greater detail, the first metal gate structures 170 are formed and may wrap around the respective semiconductor layers 102. In some embodiments, each of the first metal gate structures 170 may include the gate dielectric layer 174 and the gate electrode 176 over the gate dielectric layer 174.

Gate electrodes 276 are formed in the gate trenches and over the first metal gate structures 170. Accordingly, second metal gate structures 270 are formed. In greater detail, the second metal gate structures 270 are formed in upper portions of the gate trenches GT1 and above the first metal gate structures 170, such that the second metal gate structures 270 may wrap around the respective semiconductor layers 204. In some embodiments, each of the second metal gate structures 270 may include the gate dielectric layer 274 and the gate electrode 276 over the gate dielectric layer 274.

In some embodiments, the interfacial layers may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 and 276 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s). In some embodiments, the gate electrodes 176 may include n-type work function metal layer, while the gate electrodes 276 may include p-type work function metal layer. In some embodiments, the gate electrodes 176 and 276 are isolated from each other by dielectric.

After the metal gate structures 170 and 270 are formed, source/drain contacts 280 are formed in the isolation structures 250 and in contact with the second source/drain epitaxy structures 240, respectively. In some embodiments, the source/drain contacts 280 may be formed by, for example, etching the isolation structures 250 to form openings in the isolation structures 250 that expose the second source/drain epitaxy structures 240, filling the openings with conductive material(s), and then performing a planarization process, such as CMP, to remove excess conductive material(s). In some embodiments, each of the source/drain contacts 280 may include a diffusion barrier layer and a contact plug over the diffusion barrier layer. The diffusion barrier layer may include tantalum-based or titanium-based material, such as tantalum nitride (TaN), titanium nitride (TiN), titanium oxide (TiO), titanium (Ti), or the like. The contact plug may include tungsten (W), copper (Cu), aluminum (Al), ruthenium (Ru), cobalt (Co), molybdenum (Mo), nickel (Ni), or other suitable conductive material.

In one or more embodiments, the semiconductor channel layers 102 and the inner spacers 118 form vertical sidewalls under the isolation layer 117, and the semiconductor channel layers 204, the inner spacers 116 and the gate spacer 115 form vertical sidewalls above the isolation layer 117. The first source/drain epitaxy structures 140 and the second source/drain epitaxy structures 240 have vertical sidewalls. The isolation structures 150 have tapered sidewalls over tapered sidewalls of the isolation layer 117. As illustrated in FIG. 17A, a width W1 of the semiconductor channel layers 102 is greater than a width W2 of the semiconductor channel layers 204. A width of the metal gate structures 170 between the inner spacers 118 is greater than a width of the metal gate structure 270 between the inner spacer 116. The first source/drain epitaxy structures 140 have a width less than a width of the second source/drain epitaxy structures 240.

In some embodiment, the width W2 is provided based on a width of the dummy gate structure 130 and the gate spacer 115, and the width is provided based on patterning of the semiconductor layer 105 using the mask layer 125, as illustrated in FIGS. 6 through 9.

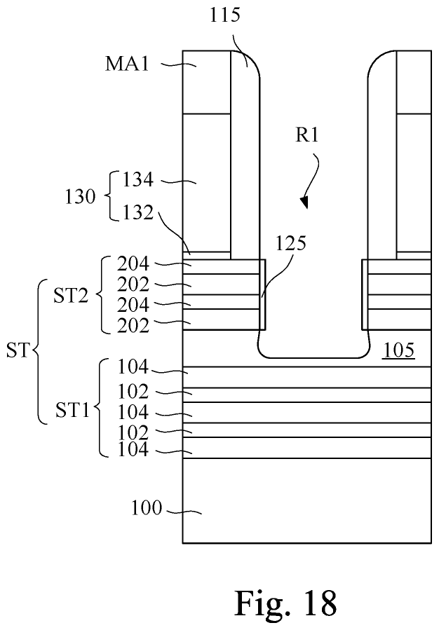

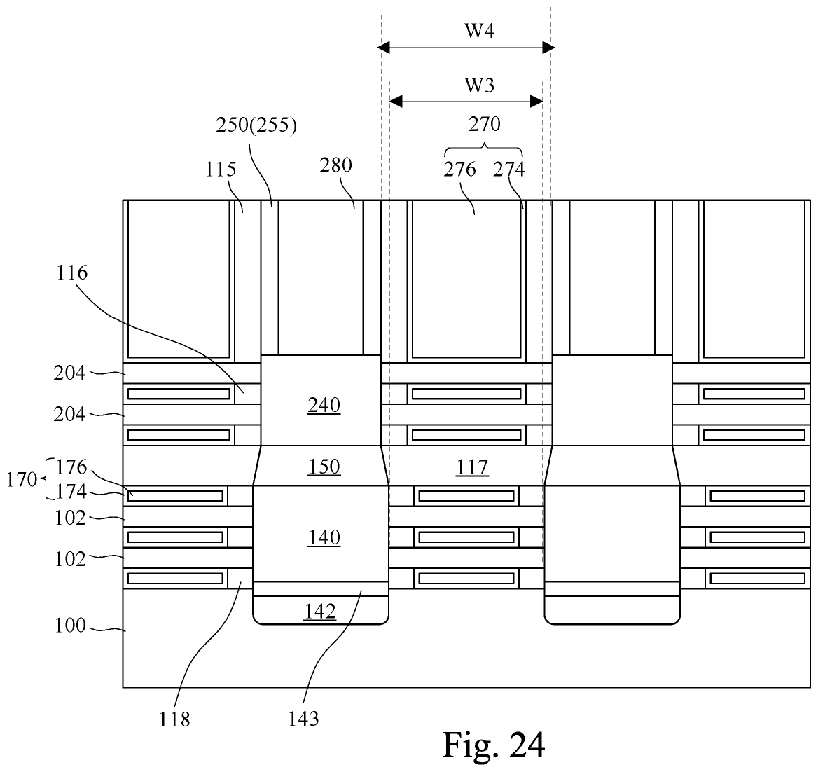

FIGS. 18 through 24 illustrate a method in various stages of forming a semiconductor device in accordance with some embodiments of the present disclosure. In greater detail, FIGS. 18 through 23 include cross-sectional views multi-steps etching process to the semiconductor fins, and FIG. 24 illustrates a detailed structure of the CFET 10 of FIG. 1, wherein FIGS. 18 through 24 continues from FIG. 7 and illustrate etching the semiconductor layer 105. It is noted that FIG. 24 include cross-sectional views the same as the cross-sectional view along line A-A of FIG. 1.

Reference is made to FIG. 18. The semiconductor layer 105 exposed from the mask layer 125 is etched. In some embodiments, the semiconductor layer 105 may be etched by an isotropic etching process. The semiconductor layer 105 is laterally etched by the isotropic etching process, so that the bottom of the recess R1 expands.

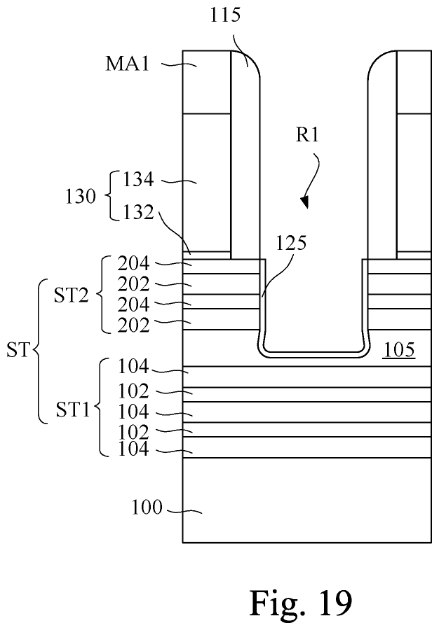

Reference is made to FIG. 19. A mask layer is formed over the exposed bottom surface of the recess R1. In some embodiments, the mask layer formed over the exposed bottom surface of the recess R1 may be a polymer layer in-situ deposited over the semiconductor layer 105. The mask layer on the sidewalls of the semiconductor channel layer 204 and the semiconductor layer 202 and the mask layer formed over the exposed bottom surface of the recess R1 may be collectively regarded as the mask layer 125.

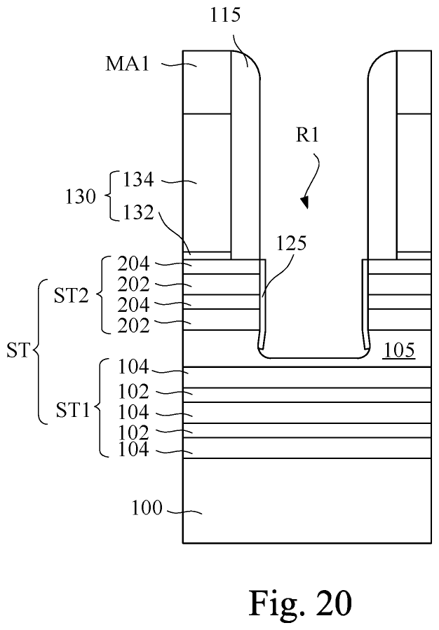

Reference is made to FIG. 20. The mask layer 125 is further patterned to expose the extending bottom of the recess R1.

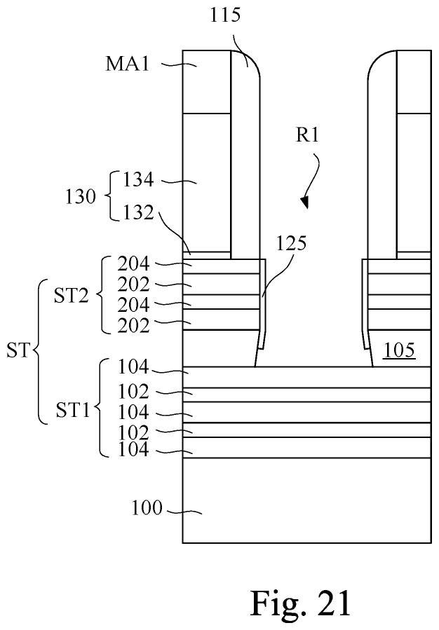

Reference is made to FIG. 21. The semiconductor layer 105 exposed from the mask layer 125 is etched through by an isotropic etching process. The semiconductor layer 105 is laterally etched by the isotropic etching process, so that the bottom of the recess R1 expands and extends to the top surface of the semiconductor layer 104.

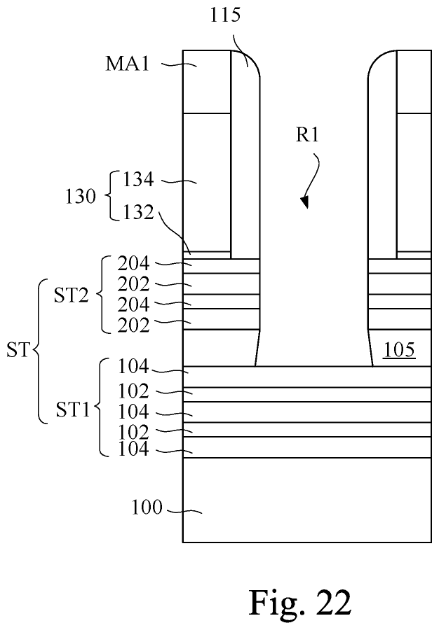

Reference is made to FIG. 22. After the semiconductor layer 105 is etched through, in FIG. 21, the remaining mask layer 125 is removed. An opening is formed through the semiconductor layer 105. Since the semiconductor layer 105 is etched based by isotropic etching processes having ability of laterally etching, the opening through the semiconductor layer 105 expands from top to bottom. Therefore, the semiconductor layer 105 may have a bottom surface and a top surface wider than the bottom surface.

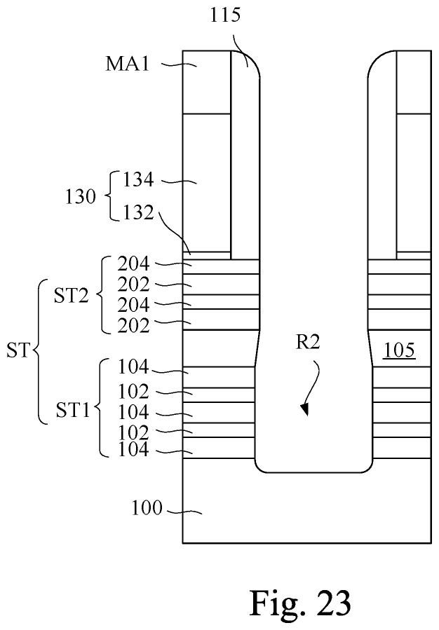

Reference is made to FIG. 23. An etching process is performed to the semiconductor channel layers 102 and the semiconductor layers 104 of the first semiconductor stack ST1 based on the patterned semiconductor layer 105. In greater detail, the etching process removes portions of the semiconductor layers 102 and 104, so as to form recesses R2 in the first stack ST1. In some embodiments, the exposed portions of the substrate 100 may be slightly etched during the etching process, and thus the bottom surfaces of the recesses R2 may be lower than top surface of the substrate 100. In some embodiments, the etching process may be wet etch, dry etch, or combinations thereof.

Reference is made to FIG. 24. FIG. 24 illustrates a structure formed through FIGS. 18-23. A difference between the structure in FIG. 17A and the structure in FIG. 24 includes that in FIG. 24, a width W3 of the semiconductor channel layers 102 is less than a width W4 of the semiconductor channel layers 204.

FIGS. 2A though 17B illustrate etching the semiconductor layer 105 by the mask layer 125 to form the CFET structure having the top metal gate structure 270 narrower than the bottom metal gate structure 170. FIGS. 18 through 24 illustrate performing an isotropic etching process, which has ability of lateral etching, to the semiconductor layer 105 using the mask layer 125 to form the CFET structure having the top metal gate structure 270 wilder than the bottom metal gate structure 170. In one or more embodiments of the present disclosure, one or more layers of the semiconductor channel layers 204, the semiconductor layers 202, the semiconductor channel layers 102 and the semiconductor layers 104 may be profiled by the etching process similar to the method as illustrated in FIGS. 6 through 9 or FIGS. 18 through 22.

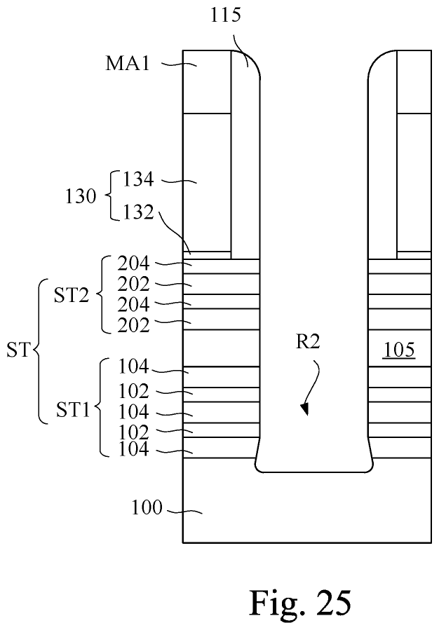

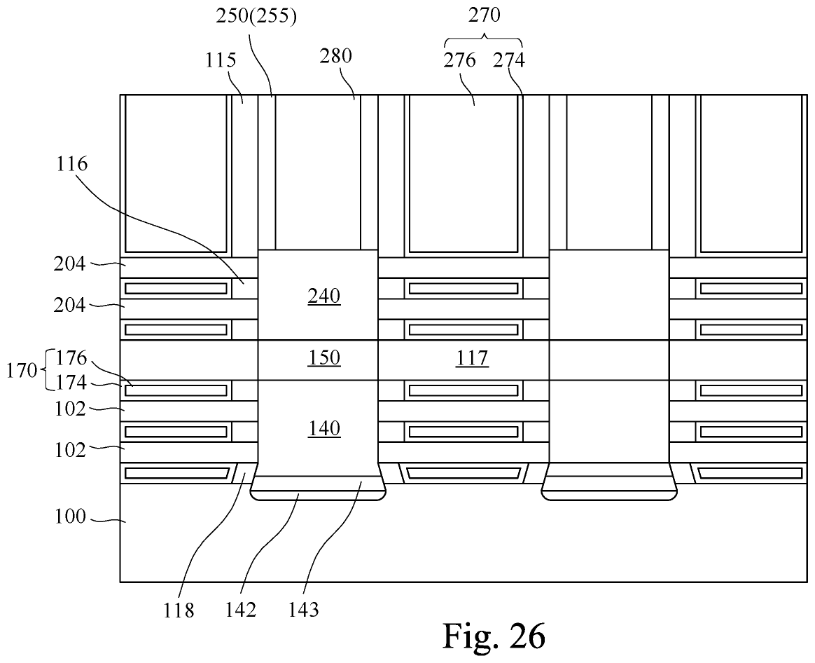

Reference is made to FIGS. 25 and 26 to illustrate profiling the metal gate structure 170 by etching the semiconductor layer 104. In greater detail, FIG. 25 includes a cross-sectional view of etching process in an intermediate stage and FIG. 26 illustrates a detailed structure of the CFET 10 of FIG. 1. It is noted that FIG. 26 include cross-sectional views the same as the cross-sectional view along line A-A of FIG. 1.

As shown in FIG. 25, layers of the semiconductor stack ST are vertically, and an isotropic etching process is performed to the bottommost layer of the semiconductor layer 104, so that bottom of the recess R2 is expand outwards.

FIG. 26 illustrates the structure formed through an intermediate stage of FIG. 25. A difference between the structure in FIG. 17A and the structure in FIG. 26 includes that in FIG. 26, the metal gate structures 170 between the substrate 100 and the bottommost semiconductor channel layer 102 have trapezoid profiles narrowing from top to bottom and. In FIG. 26, the bottommost inner spacers 118 have tapered sidewalls. The source/drain epitaxy structures 140 have vertical sidewalls and tapered sidewalls connected to the vertical sidewalls thereof.

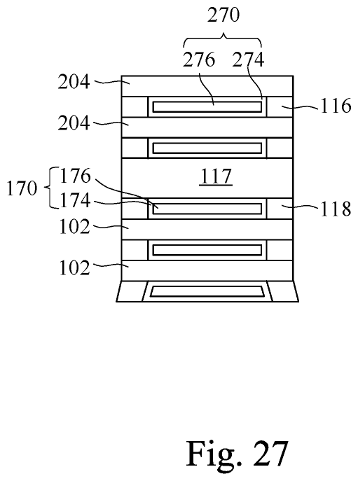

FIGS. 25 and 26 illustrate example embodiments that the profile of the metal gate structures 170 is control through the isotropic etching process to the bottommost semiconductor layer 104. Reference is made to FIGS. 27 through 33 to illustrate local cross-sectional views of channel regions and metal gate structures of various semiconductor devices in accordance with some embodiments of the present disclosure, wherein the channel regions and the metal gate structures have profiles controlled by the mask layer 125 and the etching process to the semiconductor channel layers 102, 204 and/or the semiconductor layers 104, 202. As illustrated in FIGS. 27 through 33, one or both of the first gate structure 170 and the second gate structure 270 has a tapered profile.

Reference is made to FIG. 27. FIG. 27 illustrates that the metal gate structure 170 under the bottommost semiconductor channel layer 102 has a bottom width and a top width less than the bottom width thereof.

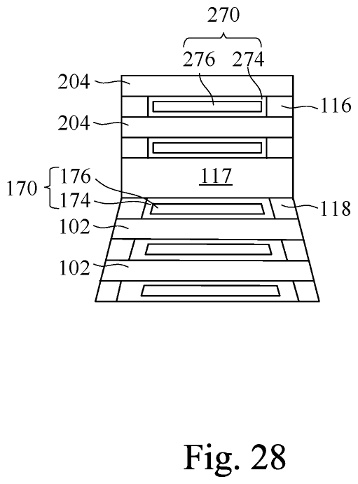

Reference is made to FIG. 28. A difference between the structure in FIG. 27 and the structure in FIG. 28 includes that in FIG. 28, a stack of the semiconductor channel layers 102, the inner spacers 118 and the metal gate structures 170 under the isolation layer 117 expands from top to bottom. In some embodiments, the structure in FIG. 28 may be formed by etching the semiconductor channel layers 102 and the semiconductor layers 104 under the semiconductor layer 105 replaced with the isolation layer 117.

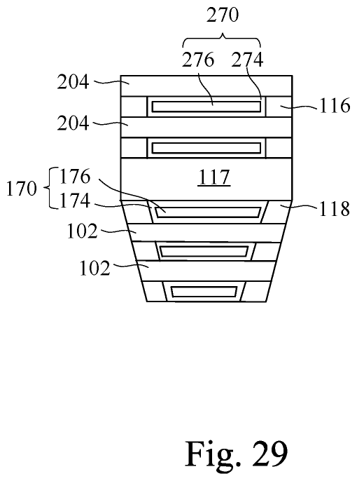

Reference is made to FIG. 29. A difference between the structure in FIG. 27 and the structure in FIG. 29 includes that in FIG. 29, the stack of the semiconductor channel layers 102, the inner spacers 118 and the metal gate structures 170 narrow from top to bottom.

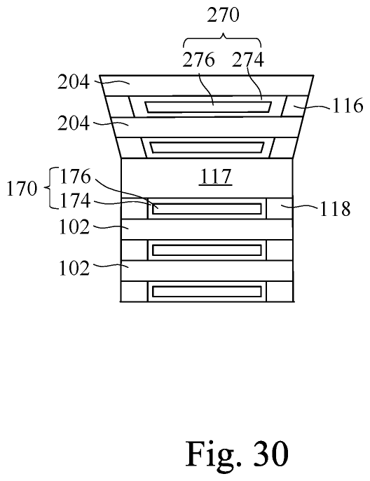

Reference is made to FIG. 30. In FIG. 30, a stack of the semiconductor channel layers 102, the inner spacers 118 under the isolation layer 117 have vertical sidewalls. A stack of the semiconductor channel layers 204, the inner spacers 116 and the metal gate structure 270 narrows from top to bottom. In some embodiments, the structure in FIG. 30 may be formed by profiling the semiconductor channel layers 204 and the semiconductor layers 202 above the semiconductor layer 105 replaced with the isolation layer 117.

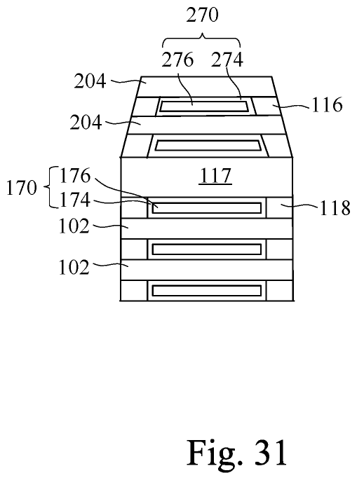

Reference is made to FIG. 31. A difference between the structure in FIG. 30 and the structure in FIG. 31 includes that in FIG. 31, the stack of the semiconductor channel layers 204, the inner spacers 116 and the metal gate structure 270 extends from top to bottom. In some embodiments, the structure in FIG. 30 may be formed by performing isotropic etching processes to the semiconductor channel layers 204 and the semiconductor layers 202 above the semiconductor layer 105 replaced with the isolation layer 117.

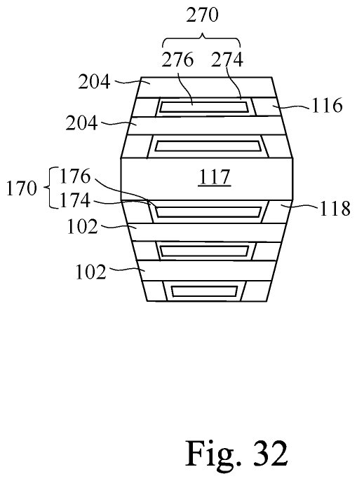

Reference is made to FIG. 32. A difference between the structure in FIG. 31 and the structure in FIG. 32 includes that in FIG. 32, the stack of the semiconductor channel layers 102, the inner spacers 118 and the metal gate structures 170 narrow from top to bottom.

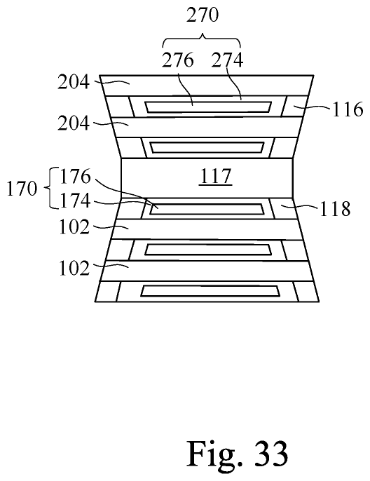

Reference is made to FIG. 33. A difference between the structure in FIG. 30 and the structure in FIG. 33 includes that in FIG. 33, the stack of the semiconductor channel layers 102, the inner spacers 118 and the metal gate structures 170 under the isolation layer 117 expands from top to bottom.

According to one or more embodiments of the present disclosure, a method includes a number of operations. A semiconductor stack structure is formed over a substrate, wherein the semiconductor stack structure includes a first semiconductor stack including first channel layers, a second semiconductor stack including second channel layers over the first semiconductor stack and a sacrificial layer between the first and second semiconductor stacks. The second semiconductor stack is etched. The sacrificial layer is etched such that a top width of the sacrificial layer is different from a bottom width of the sacrificial layer. The first semiconductor stack is etched. The sacrificial layer is replaced with an isolation layer. First source/drain regions are formed on opposite sides of the first channel layers. Second source/drain regions are formed on opposite sides of the second channel layers. A first gate structure is formed around the first channel layers. A second gate structure is formed around the second channel layers. In one or more embodiments of the present disclosure, the first gate structure has a width different from a width of the second gate structure. In one or more embodiments of the present disclosure, the first gate structure has a width greater than a width of the second gate structure. In one or more embodiments of the present disclosure, the first gate structure has a width less than a width of the second gate structure. In one or more embodiments of the present disclosure, replacing the sacrificial layer with the isolation layer includes a number of operations. The sacrificial layer is removed to form a gap between the first semiconductor stack and the second semiconductor stack. An isolation material is formed to fill the gap between the first and second semiconductor stacks. A first portion of the isolation material is removed out of the gap, while leaving a second portion of the isolation material in the gap. In one or more embodiments of the present disclosure, after etching the first semiconductor stack, the first semiconductor stack has a width different from a width of the second semiconductor stack. In one or more embodiments of the present disclosure, the method further includes forming isolation structures over the first source/drain regions, wherein the second source/drain regions are formed over the isolation structures, and each of the isolation structures has a tapered sidewall.

According to one or more embodiments of the present disclosure, a method includes a number of operations. A first semiconductor stack of first sacrificial layers and first semiconductor layers alternately stacked over a substrate is formed. A sacrificial layer is formed over the first semiconductor stack. A second semiconductor stack of second sacrificial layers and second semiconductor layers alternately stacked over the sacrificial layer is formed. Source/drain recess is formed and extend through the first semiconductor stack, the sacrificial layer and the second semiconductor stack, wherein the source/drain recess includes a first portion level with the first semiconductor stack, and a second portion level with the second semiconductor stack, and the second portion has a width different from a width of the first portion. The sacrificial layer is replaced with an isolation layer. A first source/drain region is formed in the first portion of the source/drain recess. A second source/drain region is formed in the second portion of the source/drain recess. The first sacrificial layers are replaced with a first gate structure. The second sacrificial layers are replaced with a second gate structure. In one or more embodiments of the present disclosure, the width of the first portion of the source/drain recess is less than the width of the second portion of the source/drain recess. In one or more embodiments of the present disclosure, the first source/drain region has a width less than a width of the second source/drain region. In one or more embodiments of the present disclosure, the first gate structure has a width different from a width of the second gate structure. In one or more embodiments of the present disclosure, the method further includes forming first inner spacers on opposite sidewalls of the first sacrificial layers and forming second inner spacers on opposite sidewalls of the second sacrificial layers, wherein the second inner spacers are laterally offset from the first inner spacers. In one or more embodiments of the present disclosure, the method further includes forming an isolation structure on the first source/drain region, the isolation structure has a width changing as a function of height. In some embodiments, the isolation structure forms a sloped interface with the isolation layer. In some embodiments, the width of the isolation structure increases as a distance from the first source/drain region increases. In one or more embodiments of the present disclosure, a top width of the first source/drain regions is different from a bottom width of the first source/drain regions.

According to one or more embodiments of the present disclosure, a semiconductor device includes a first transistor over a substrate, an isolation layer over the first transistor and a second transistor over the isolation layer. The first transistor includes a first semiconductor channel layer, first source/drain epitaxy structures on opposite ends of the first semiconductor channel layer and a first gate structure wrapping around the first semiconductor channel layer. The second transistor includes a second semiconductor channel layer, second source/drain epitaxy structures on opposite ends of the second semiconductor channel layer and a second gate structure over the isolation layer and wrapping around the second semiconductor channel layer. A width of the second gate structure is different from a width of the first gate structure. In one or more embodiments of the present disclosure, a bottom surface of the isolation layer has a width different from a width of a top surface of the isolation layer. In one or more embodiments of the present disclosure, the semiconductor device further includes a plurality of isolation structures between the first and second source/drain epitaxy structures. Each of the isolation structures has a tapered sidewall. In one or more embodiments of the present disclosure, one or both of the first gate structure and the second gate structure has a tapered profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a semiconductor stack structure over a substrate, wherein the semiconductor stack structure comprises a first semiconductor stack comprising first channel layers, a second semiconductor stack comprising second channel layers over the first semiconductor stack and a sacrificial layer between the first and second semiconductor stacks;
etching the second semiconductor stack;
etching the sacrificial layer such that a top width of the sacrificial layer is different from a bottom width of the sacrificial layer;
etching the first semiconductor stack;
replacing the sacrificial layer with an isolation layer;
forming first source/drain regions on opposite sides of the first channel layers;
forming second source/drain regions on opposite sides of the second channel layers;
forming a first gate structure around the first channel layers; and
forming a second gate structure around the second channel layers.

2. The method of claim 1, wherein the first gate structure has a width different from a width of the second gate structure.

3. The method of claim 1, wherein the first gate structure has a width greater than a width of the second gate structure.

4. The method of claim 1, wherein the first gate structure has a width less than a width of the second gate structure.

5. The method of claim 1, wherein replacing the sacrificial layer with the isolation layer comprises:
removing the sacrificial layer to form a gap between the first semiconductor stack and the second semiconductor stack;
forming an isolation material to fill the gap between the first and second semiconductor stacks; and
removing a first portion of the isolation material out of the gap, while leaving a second portion of the isolation material in the gap.

6. The method of claim 1, wherein after etching the first semiconductor stack, the first semiconductor stack has a width different from a width of the second semiconductor stack.

7. The method of claim 1, further comprising:
forming isolation structures over the first source/drain regions, wherein the second source/drain regions are formed over the isolation structures, and each of the isolation structures has a tapered sidewall.

8. A method comprising:
forming a first semiconductor stack of first sacrificial layers and first semiconductor layers alternately stacked over a substrate;
forming a sacrificial layer over the first semiconductor stack;
forming a second semiconductor stack of second sacrificial layers and second semiconductor layers alternately stacked over the sacrificial layer;
forming a source/drain recess extending through the first semiconductor stack, the sacrificial layer and the second semiconductor stack, wherein the source/drain recess comprises a first portion level with the first semiconductor stack, and a second portion level with the second semiconductor stack, and the second portion has a width different from a width of the first portion;
replacing the sacrificial layer with an isolation layer;
forming a first source/drain region in the first portion of the source/drain recess;
forming a second source/drain region in the second portion of the source/drain recess;
replacing the first sacrificial layers with a first gate structure; and
replacing the second sacrificial layers with a second gate structure.

9. The method of claim 8, wherein the width of the first portion of the source/drain recess is less than the width of the second portion of the source/drain recess.

10. The method of claim 8, wherein the first source/drain region has a width less than a width of the second source/drain region.

11. The method of claim 8, wherein the first gate structure has a width different from a width of the second gate structure.

12. The method of claim 8, further comprising:
forming first inner spacers on opposite sidewalls of the first sacrificial layers; and
forming second inner spacers on opposite sidewalls of the second sacrificial layers, wherein the second inner spacers are laterally offset from the first inner spacers.

13. The method of claim 8, further comprising:
forming an isolation structure on the first source/drain region, wherein the isolation structure has a width changing as a function of height.

14. The method of claim 13, wherein the isolation structure forms a sloped interface with the isolation layer.

15. The method of claim 13, wherein the width of the isolation structure increases as a distance from the first source/drain region increases.

16. The method of claim 8, wherein a top width of the first source/drain regions is different from a bottom width of the first source/drain regions.

17. A semiconductor device comprising:
a first transistor over a substrate, comprising:
a first semiconductor channel layer;
first source/drain epitaxy structures on opposite ends of the first semiconductor channel layer; and
a first gate structure wrapping around the first semiconductor channel layer;
an isolation layer over the first gate structure; and
a second transistor above the first transistor, comprising:
a second semiconductor channel layer;
second source/drain epitaxy structures on opposite ends of the second semiconductor channel layer; and
a second gate structure over the isolation layer and wrapping around the second semiconductor channel layer, wherein a width of the second gate structure is different from a width of the first gate structure.

18. The semiconductor device of claim 17, wherein a bottom surface of the isolation layer has a width different from a width of a top surface of the isolation layer.

19. The semiconductor device of claim 17, further comprising:
a plurality of isolation structures between the first and second source/drain epitaxy structures, wherein each of the isolation structures has a tapered sidewall.

20. The semiconductor device of claim 17, wherein one or both of the first gate structure and the second gate structure has a tapered profile.
